(19) United States
(12) Patent Application Publication
(10) Pub. No.: US 2016/0336452 A1
(43) Pub. Date: Nov. 17, 2016

(54) Thin Film Transistor and Method of Fabricating the Same, Array Substrate, and Display Device

(71) Applicant: BOE TECHNOLOGY GROUP CO., LTD., Beijing (CN)

(72) Inventor: Meili WANG, Beijing (CN)

(21) Appl. No.: 14/905,375

(22) PCT Filed: May 18, 2015
(86) PCT No.: PCT/CN2015/079162

§ 371 Date: Jan. 15, 2016

(30) Foreign Application Priority Data
Jan. 15, 2015 (CN) 201510020616.X

(51) Int. Cl. H01L 29/786; H01L 21/383; H01L 27/12; H01L 29/36; H01L 29/66

(52) U.S. Cl. CPC H01L 29/7869; H01L 29/36; H01L 29/66969; H01L 27/1225; H01L 21/383

(57) ABSTRACT

The present invention provides a thin film transistor and a method of fabricating the same, an array substrate and a display device. The thin film transistor comprises a gate, an active layer, a source and a drain formed on a substrate, the active layer comprises an oxide having doped ions, the doped ions have a p-orbital electron arrangement structure, and an energy level of p-orbital of the doped ions is higher than that of 2p-orbital of oxygen ions in the oxide, so that top of valence band of the active layer is higher than the energy level of oxygen vacancies formed in the oxide. The active layer of the thin film transistor is made of the oxide having the doped ions, which may improve a stability of the thin film transistor, and there is no need to add a light blocking structure in the display device.

### FIELD OF THE INVENTION

The present invention relates to the field of display technology, and particularly to a thin film transistor and a method of fabricating the thin film transistor, an array substrate comprising the thin film transistor, and a display device comprising the array substrate.

### BACKGROUND OF THE INVENTION

An oxide thin film transistor has advantages of good uniformity, transparency, simple fabricating process, etc., and has a concentration of carriers ten times or even dozens of times than that of an amorphous silicon thin film transistor, and thus has got a lot of attention in the fields of liquid crystal display device, organic light emitting diode display device, etc.

However, a problem of poor light stability exists in the oxide thin film transistor such as indium gallium zinc oxide (IGZO) and indium tin zinc oxide (ITZO) thin film transistor, that is, a threshold voltage of the thin film transistor (TFT) may shift under the condition of illumination, or the thin film transistor may even fail, which seriously affects a mass production of the oxide TFT.

A large number of intrinsic defects such as oxygen vacancies, zinc vacancies, oxygen gaps, zinc gaps may be generated in zinc oxide-based semiconductor material. As for the intrinsic defects, a gap-type defect may have less impact on the carriers in the semiconductor, while a vacancy-type defect may provide two electrons under the condition of illumination and have large impact on the stability of TFT. As for the intrinsic defects of the zinc oxide, formation energy of the oxygen vacancy is 3.78 eV, which is lower than that of the zinc vacancy (4.75 eV), and thus a defect density of the oxygen vacancies is much higher than that of the zinc vacancies. Therefore, the oxygen vacancy becomes a main defect state that affects the light stability of the oxide thin film transistor.

In the prior art, the thin film transistor is covered by a light blocking material in order to reduce the impact of illumination on the oxide thin film transistor, or light blocking protection is applied to the thin film transistor on a display backplane so as to reduce the impact of illumination on the thin film transistor. However, these methods increase the fabrication cost and complicate the fabrication process.

### SUMMARY OF THE INVENTION

An objective of the present invention is to provide a thin film transistor and a method of fabricating the thin film transistor, an array substrate comprising the thin film transistor, and a display device comprising the array substrate, so that the stability of the thin film transistor can be improved without increasing the fabrication cost.

In order to achieve the above objective, the present invention provides a thin film transistor, comprising a gate, an active layer, a source and a drain formed on a substrate, the active layer comprises an oxide having doped ions, the doped ions have a p-orbital electron arrangement structure, and an energy level of p-orbital of the doped ions is higher than that of 2p-orbital of oxygen ions in the oxide, so that top of valence band of the active layer is higher than the energy level of oxygen vacancies formed in the oxide.

The doped ions may comprise at least one kind of ions of F⁻, N³⁻, S²⁻, Se^{e-} and P³⁻.

The oxide may comprise a metal oxide containing at least one of indium, gallium, zinc, hafnium, tin and aluminum.

The oxide may comprise zinc oxide, the doped ions may comprise N³⁻ or S²⁻, a molar ratio of the doped ions in the total amount of the doped ions and the oxygen ions in the oxide may range from 5% to 80%.

The present invention further provides an array substrate comprising the above thin film transistor.

The present invention further provides a display device comprising the above array substrate.

The present invention further provides a method of fabricating a thin film transistor, comprising steps of: forming a pattern comprising a gate on a substrate; forming a pattern comprising an active layer, wherein the active layer comprises an oxide having doped ions, the doped ions have a p-orbital electron arrangement structure, and an energy level of p-orbital of the doped ions is higher than that of 2p-orbital of oxygen ions in the oxide, so that top of valence band of the active layer is higher than the energy level of oxygen vacancies formed in the oxide; and forming a pattern comprising a source and a drain.

The doped ions may comprise at least one kind of ions of F⁻, N³⁻, S²⁻, Se^{e-} and P³⁻.

The oxide may comprise a metal oxide containing at least one of indium, gallium, zinc, hafnium, tin and aluminum.

In the method, the step of forming the pattern comprising the active layer comprises: introducing process gases into a reaction chamber to bombard a target material, wherein the process gases comprise an argon gas, an oxygen-containing gas and a doped ion providing gas, a volume percentage of the doped ion providing gas in the process gases ranges from 5% to 95%.

The oxide may comprise zinc oxide, and the doped ion providing gas may comprise a nitrogen-containing gas or a sulfur-containing gas.

Further, a ratio of the nitrogen-containing gas in the process gases is adjusted so that a molar ratio of nitrogen ions in the total amount of the nitrogen ions and the oxygen ions in the active layer ranges from 5% to 80%, or a ratio of the sulfur-containing gas in the process gases is adjusted so that a molar ratio of sulfur ions in the total amount of the sulfur ions and the oxygen ions in the active layer ranges from 5% to 80%.

A flow rate of the argon gas may range from 5 sccm to 300 sccm, and a flow rate of the oxygen-containing gas may range from 5 sccm to 200 sccm.

The active layer of the thin film transistor of the embodiments of the present invention comprises the doped ions having the energy level of p-orbital higher than that of 2p-orbital of oxygen ions, so that the top of valence band of the active layer is elevated, thereby reducing the number of the oxygen vacancies, reducing the density of defect states of the active layer, and improving the stability of the thin film transistor. The light blocking method performed on the thin film transistor in the prior art does not reduce the density of defect states of the active layer. Compared with the prior art, the present invention may improve the active layer itself, there is no need to add the light blocking structure, and thus the fabrication cost and the process complexity may be reduced.

### BRIEF DESCRIPTION OF THE DRAWINGS

The accompanying drawings which constitute a part of the description are used for providing further understanding of the present invention and for explaining the present invention in conjunction with the following specific embodiments, rather than limiting the present invention. In the accompanying drawings:

FIG. 1 is a schematic diagram of valence bands of an active layer before and after adjustment.

### DESCRIPTION OF THE PREFERRED EMBODIMENT

Hereinafter, specific embodiments of the present invention will be described in detail with reference to the accompanying drawings. It should be understood that the embodiments described herein are only employed for illustrating and explaining the present invention, rather than limiting the present invention.

According to an aspect of the present invention, a thin film transistor comprises a gate, an active layer, a source and a drain formed on a substrate. The active layer of the thin film transistor comprises an oxide having doped ions, the doped ions has a p-orbital electron arrangement structure, and an energy level of p-orbital of the doped ions is higher than that of 2p-orbital of oxygen ions in the oxide, so that top of valence band of the active layer is higher than the energy level of oxygen vacancies formed due to oxygen deficiency in the oxide.

As for metal oxide, oxygen detachment may occur in lattices in a particular external environment, resulting in the oxygen deficiency and forming the oxygen vacancy. The person skilled in the art may understand that bottom of conduction band (CBM) of material of the oxide active layer consists of metal ion orbitals, and top of valence band (VBM) consists of 2p-orbital of oxygen ions. The active layer of the thin film transistor of the present invention comprises the doped ions having the energy level of p-orbital higher than that of 2p-orbital of oxygen ions, so that the top of valence band of the active layer is elevated.

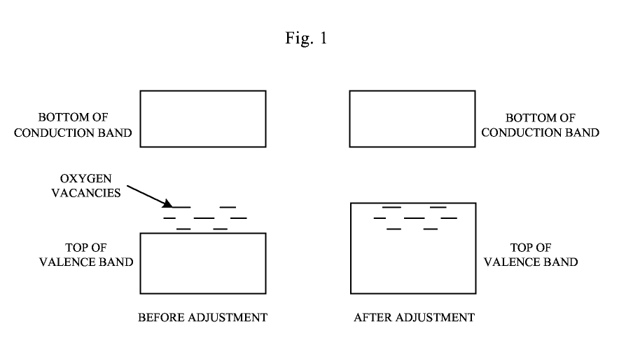

As shown in FIG. 1, before a valence band adjustment is performed on the active layer, the oxygen vacancies Vo are located between the top of valence band (VBM) of the active layer and the bottom conduction band (CBM) of the active layer. After an energy band adjustment is performed on the active layer, a band gap of the active layer is reduced, and the top of valence band is elevated until the top of valence band is higher than the energy level of the oxygen vacancies Vo. In this case, the number of the oxygen vacancies Vo is reduced, thereby reducing the density of defect states of the active layer, and further improving the stability of the thin film transistor. The light blocking method performed on the thin film transistor in the prior art does not reduce the density of defect states of the active layer. Compared with the prior art, the present invention may improve the active layer itself without adding the light blocking structure. Therefore, the present invention may reduce the fabrication cost and the process complexity.

The types of the doped ions are not limited in the present invention. As a specific embodiment of the present invention, the doped ions may comprise at least one kind of ions of F⁻, N³⁻, S²⁻, Se^{e-} and P³⁻, i.e., the doped ions may comprise any one kind of ions of the above-mentioned ions, or may comprise a combination of two or more kinds of the above-mentioned ions. The electron arrangement of F⁻ is 1s²2s²2p⁶, the electron arrangement of N³⁻ is 1s²2s²2p⁶, the electron arrangement of S²⁻ is 1s²2s²2p⁶3s²3p⁶, the electron arrangement of Se^{e-} is 1s²2s²2p⁶3s²3p⁶3d¹⁰4s²4p⁶, the electron arrangement of P³⁻ is 1s²2s²2p⁶3s²3p⁶, and the electron arrangement of O²⁻ is 1s²2s²2p⁶. Of course, the doped ions may comprise other ions, as long as the ions have the p-orbital electron arrangement structure and have the energy level of p-orbital higher than that of 2p-orbital of O²⁻. In the present invention, the oxide may comprise a metal oxide containing at least one of indium, gallium, zinc, hafnium, tin and aluminum, e.g., zinc oxide, tin oxide and indium tin oxide.

As a specific embodiment of the present invention, the oxide comprises zinc oxide, the doped ions comprise N³⁻ or S²⁻, a molar ratio of the doped ions in the total amount of the doped ions and the oxygen ions in the oxide ranges from 5% to 80%, i.e., the molar ratio satisfies: 5%≦N³⁻/(N³⁻+O²⁻)≦80%, or 5% ≦S²⁻/(S²⁻+O²⁻)≦80%. The band gap of zinc oxide is 3.32 eV, the band gaps of zinc nitride and zinc sulfide are both 1.1 eV. When the doped ions comprise N³⁻, the band gap of the active layer (i.e., the zinc oxide layer doped with N³⁻) is smaller than that of zinc oxide, the top of valence band moves upwardly so that the oxygen vacancies Vo are reduced. Similarly, when the doped ions comprise S²⁻, the band gap of the active layer (i.e., the zinc oxide layer doped with S²⁻) is also smaller than that of zinc oxide, the top of valence band moves upwardly so that the oxygen vacancies Vo are reduced.

The thin film transistor may further comprise a gate insulation layer provided between the gate and the active layer.

As can be seen from above description of the thin film transistor according to the embodiments of the present invention, the active layer comprises the doped ions having the energy level of p-orbital higher than that of 2p-orbital of oxygen ions, so that the top of valence band of the active layer is elevated, and when the top of valence band of the active layer is higher than the energy level of the oxygen vacancies Vo, the number of the oxygen vacancies may be reduced and the density of defect states of the active layer may be reduced, thereby improving the stability of the thin film transistor and prolonging the service life of the thin film transistor.

As another aspect of the present invention, an array substrate comprises the above thin film transistor according to the embodiments of the present invention.

As yet another aspect of the present invention, a method of fabricating a thin film transistor comprises steps of: forming a pattern comprising a gate on a substrate; forming a pattern comprising an active layer, wherein the active layer comprises an oxide having doped ions, the doped ions has a p-orbital electron arrangement structure, and an energy level of p-orbital of the doped ions is higher than that of 2p-orbital of oxygen ions in the oxide, so that top of valence band of the active layer is higher than the energy level of oxygen vacancies formed in the oxide; and forming a pattern comprising a source and a drain.

As described above, the doped ions may comprise at least one kind of ions of F⁻, N³⁻, S²⁻, Se^{e-} and P³⁻, or may be other ions having the p-orbital electron arrangement structure and having the energy level of p-orbital higher than that of 2p-orbital of oxygen ions.

The oxide may comprise a metal oxide containing at least one of indium, gallium, zinc, hafnium, tin and aluminum.

The pattern comprising the active layer may be formed by different methods, such as co-sputtering process, chemical vapor deposition process or atmosphere sintering process. As a specific embodiment of the present invention, the co-sputtering process may be utilized, i.e., a target material is provided in a vacuum reaction chamber, an inert gas is introduced into the reaction chamber, the inert gas is ionized, and then gas ions bombard the target material under the electric field, so that particles are dislodged from a surface of the target material and deposited on the substrate below, thereby forming an oxide film layer. In order to allow the oxide film layer to contain the doped ions, a gas comprising the doped ions may be introduced while the inert gas is introduced.

Specifically, the step of forming the pattern comprising the active layer comprises: introducing process gases into the reaction chamber to bombard the target material, the process gases comprise an argon gas, an oxygen-containing gas and a doped ion providing gas, a volume percentage of the doped ion providing gas in the process gases ranges from 5% to 95%.

Further, the oxide may comprise zinc oxide, the doped ion providing gas may comprise a nitrogen-containing gas (e.g., nitrogen, nitrous oxide, ammonia, etc.) or a sulfur-containing gas (e.g., sulfur dioxide, silane, etc.). The target material may be a zinc target material or a zinc oxide target material. The process gases bombard the target material to form the zinc oxide film layer, a ratio of the nitrogen-containing gas in the process gases is adjusted so that a molar ratio of nitrogen ions in the total amount of the oxygen ions and the nitrogen ions in the active layer ranges from 5% to 80%, or a ratio of the sulfur-containing gas in the process gases is adjusted so that a molar ratio of sulfur ions in the total amount of the oxygen ions and the sulfur ions in the active layer ranges from 5% to 80%.

For example, a flow rate of the argon gas ranges from 5 sccm to 300 sccm, a flow rate of the oxygen-containing gas ranges from 5 sccm to 200 sccm. The argon gas is used to physically bombard the target material, and the oxygen-containing gas is used to oxidize the particles dislodged from the target material to form metal oxide. The flow rates of the argon gas and the oxygen-containing gas are adjusted so that a thickness of the active layer and a concentration of the oxygen ions fall within the desired range.

After forming the zinc oxide film layer comprising the doped ions by the co-sputtering process, a pattern comprising the active layer is formed by performing a patterning process on the zinc oxide film layer.

As described above, the thin film transistor may further comprise a gate insulation layer provided between the gate and the active layer, and accordingly, the method may further comprise a step of forming a gate insulation layer.

The thin film transistor in the embodiments of the present invention may comprise a top-gate type thin film transistor, a top-gate coplanar type thin film transistor, a bottom-gate type thin film transistor, or a bottom-gate coplanar type thin film transistor. When forming the top-gate type thin film transistor, the source and the drain may be formed on the substrate first, and then the active layer, the gate insulation layer and the gate are sequentially formed on the source and the drain. When forming the top-gate coplanar type thin film transistor, the active layer may be formed on the substrate first, and then the source and the drain, the gate insulation layer and the gate are sequentially formed on the active layer. When forming the bottom-gate type thin film transistor, the gate may be formed on the substrate first, and then the gate insulation layer, the active layer, and the source and the drain are sequentially formed on the gate. When forming the bottom-gate coplanar type thin film transistor, the gate may be formed on the substrate first, and then the gate insulation layer, the source and the drain, and the active layer are sequentially formed on the gate.

As still another aspect of the present invention, a display device comprises the above array substrate. The display device may be any product or component with a display function, such as a liquid crystal panel, an electronic paper, an OLED panel, a mobile phone, a tablet computer, a TV set, a display, a laptop, a digital photo frame, a navigator, etc.

Since the thin film transistor of the embodiments of the present invention has an improved stability, the light blocking process is not required to be performed on the thin film transistor on the array substrate or the display device, thereby simplifying the product structure and the fabrication process.

It should be understood that the above embodiments are only exemplary embodiments for illustrating the principle of the present invention, but the present invention is not limited thereto. Various variations and improvements can be made by the person of ordinary skill in the art without departing from the spirit and essence of the present invention, and these variations and improvements should also be considered to fall within the protection scope of the present invention.

1-13. (canceled)

14. A thin film transistor, comprising a gate, an active layer, a source and a drain formed on a substrate, wherein
the active layer comprises an oxide having doped ions, the doped ions have a p-orbital electron arrangement structure, and an energy level of p-orbital of the doped ions is higher than that of 2p-orbital of oxygen ions in the oxide, so that top of valence band of the active layer is higher than the energy level of oxygen vacancies formed in the oxide.

15. The thin film transistor of claim 14, wherein the doped ions comprise at least one kind of ions of F−, N3−, S2−, Se2− and P3−.

16. The thin film transistor of claim 14, wherein the oxide comprises a metal oxide containing at least one of indium, gallium, zinc, hafnium, tin and aluminum.

17. The thin film transistor of claim 14, wherein the oxide comprises zinc oxide, the doped ions comprise N3− or S2−, and a molar ratio of the doped ions in the total amount of the doped ions and the oxygen ions in the oxide ranges from 5% to 80%.

18. A method of fabricating a thin film transistor, comprising steps of:
forming a pattern comprising a gate on a substrate;
forming a pattern comprising an active layer, wherein the active layer comprises an oxide having doped ions, the doped ions have a p-orbital electron arrangement structure, and an energy level of p-orbital of the doped ions is higher than that of 2p-orbital of oxygen ions in the oxide, so that top of valence band of the active layer is higher than the energy level of oxygen vacancies formed in the oxide; and
forming a pattern comprising a source and a drain.

19. The method of claim 18, wherein the doped ions comprise at least one kind of ions of F−, N3−, S2−, Se2− and P3−.

20. The method of claim 18, wherein the oxide comprises a metal oxide containing at least one of indium, gallium, zinc, hafnium, tin and aluminum.

21. The method of claim 18, wherein the step of forming the pattern comprising the active layer comprises:
introducing process gases into a reaction chamber to bombard a target material, wherein the process gases comprise an argon gas, an oxygen-containing gas and a doped ion providing gas, a volume percentage of the doped ion providing gas in the process gases ranges from 5% to 95%.

22. The method of claim 21, wherein the oxide comprises zinc oxide, and the doped ion providing gas comprises a nitrogen-containing gas or a sulfur-containing gas.

23. The method of claim 22, wherein a ratio of the nitrogen-containing gas in the process gases is adjusted so that a molar ratio of nitrogen ions in the total amount of the nitrogen ions and the oxygen ions in the active layer ranges from 5% to 80%, or a ratio of the sulfur-containing gas in the process gases is adjusted so that a molar ratio of sulfur ions in the total amount of the sulfur ions and the oxygen ions in the active layer ranges from 5% to 80%.

24. The method of claim 21, wherein a flow rate of the argon gas ranges from 5 sccm to 300 sccm, and a flow rate of the oxygen-containing gas ranges from 5 sccm to 200 sccm.

25. An array substrate, comprising thin film transistors, the thin film transistor comprising a gate, an active layer, a source and a drain formed on a substrate, wherein the active layer comprises an oxide having doped ions, the doped ions have a p-orbital electron arrangement structure, and an energy level of p-orbital of the doped ions is higher than that of 2p-orbital of oxygen ions in the oxide, so that top of valence band of the active layer is higher than the energy level of oxygen vacancies formed in the oxide.

26. The array substrate of claim 25, wherein the doped ions comprise at least one kind of ions of F−, N3−, S2−, Se2− and P3−.

27. The array substrate of claim 25, wherein the oxide comprises a metal oxide containing at least one of indium, gallium, zinc, hafnium, tin and aluminum.

28. The array substrate of claim 25, wherein the oxide comprises zinc oxide, the doped ions comprise N3− or S2−, and a molar ratio of the doped ions in the total amount of the doped ions and the oxygen ions in the oxide ranges from 5% to 80%.

29. A display device, comprising the array substrate of claim 25.
